(19) United States
(12) Patent Application Publication
(10) Pub. No.: US 2026/0056234 A1
(43) Pub. Date: Feb. 26, 2026

(54) PROBE CARD APPARATUS

(71) Applicant: VUETTE PTE. LTD., SINGAPORE (SG)

(72) Inventors: CHOON LEONG LOU, SINGAPORE (SG); HO YEH CHEN, HSINCHU COUNTY (TW); BAN BAN LIM, SINGAPORE (SG)

(21) Appl. No.: 19/015,542

(22) Filed: Jan. 9, 2025

(30) Foreign Application Priority Data
Aug. 23, 2024 (CN) 202411165606.0

(51) Int. Cl. G01R 1/073; G01R 31/28

(52) U.S. Cl. CPC G01R 1/07342; G01R 31/2889; G01R 31/2891

(57) ABSTRACT

A probe card apparatus is provided, which includes a carrier, a probe card, a fixing device, and an air pressure adjusting device. The carrier carries an object to be tested. The probe card includes a plurality of probes, and the plurality of probes are in contact with the object to be tested for testing. The fixing device is connected to the probe card and the carrier. The fixing device, the probe card, and the carrier jointly define a test chamber that is closed. The air pressure adjusting device is spatially communicated with the test chamber and used to adjust an air pressure in the test chamber to a predetermined air pressure. At least one of the carrier and the probe card is subject to a stress at the predetermined air pressure. The fixing device is used to resist the stress to maintain the test chamber that is closed.

### FIELD OF THE DISCLOSURE

The present disclosure relates to a probe card apparatus, and more particularly to a probe card apparatus including a fixing device and an air pressure adjusting device.

### BACKGROUND OF THE DISCLOSURE

With the development of the semiconductor industry, probe cards are usually applied to conduct electrical testing or reliability testing on wafers or chips to ensure the quality of wafers and chips.

With the development and application of technology, the demand for high-power chips gradually emerges. Therefore, there is increasing demand for high-voltage testing on wafers or chips to ensure the quality and reliability of wafers and chips. Since the probe card is provided with high voltage for testing, a point discharge easily occurs at the probe, which can cause damage to the components in the probe card or to the wafer (chip). In the conventional technology, in order to suppress the point discharge, the test space defined by the probe card and the chuck is usually evacuated or pressurized.

However, for example, if the probe card is used to test the wafer at two times atmospheric pressure, even if the circuit board on the probe card is provided with a structurally reinforced mechanism, the stress generated on the wafer in the test environment of two times atmospheric pressure may, in some cases, be up to one ton. As a result, the chuck or the probe card is deformed, which affects the test results and even causes apparatus damage.

Therefore, when testing wafers or chips in a vacuum or pressurized environment, how to avoid the chuck or the probe card from deforming to provide a stable testing force while suppressing the point discharge at the probe is an urgent issue to be addressed in the related field.

### SUMMARY OF THE DISCLOSURE

The present disclosure provides a probe card apparatus, which includes a carrier, a probe card, a fixing device, and an air pressure adjusting device. The carrier is used to carry an object to be tested. The probe card includes a plurality of probes, the probe card is arranged above the object to be tested, and the plurality of probes are in contact with the object to be tested for testing. The fixing device is correspondingly connected to the probe card and the carrier. The fixing device, the probe card, and the carrier jointly define a test chamber that is closed. The object to be tested is disposed in the test chamber. The air pressure adjusting device is spatially communicated with the test chamber and used to adjust an air pressure in the test chamber to a predetermined air pressure. At least one of the carrier and the probe card is subject to a stress at the predetermined air pressure. The fixing device is used to resist the stress.

In one of the possible or preferred embodiments, the air pressure adjusting device draws gas from the test chamber so that the predetermined air pressure is less than one atm.

In one of the possible or preferred embodiments, at the predetermined air pressure, a length of the fixing device in a vertical direction corresponds to a distance between the carrier and the probe card.

In one of the possible or preferred embodiments, at the predetermined air pressure, the length of the fixing device in the vertical direction corresponds to a needle pressure of the probe card applying to the object to be tested.

In one of the possible or preferred embodiments, at the predetermined air pressure, the length of the fixing device in the vertical direction corresponds to an over driving of the probe card applying to the object to be tested.

In one of the possible or preferred embodiments, the air pressure adjusting device supplies gas into the test chamber so that the predetermined air pressure is greater than one atm.

In one of the possible or preferred embodiments, the gas supplied to the test chamber by the air pressure adjusting device is air, nitrogen, or an inert gas.

In one of the possible or preferred embodiments, the fixing device is made of at least one of a metal structure and a plastic structure.

In one of the possible or preferred embodiments, the fixing device includes at least one of a clamping assembly and a screw fixing assembly.

One of the beneficial effects of the present disclosure is that in the probe card apparatus provided by the present disclosure, by virtue of “the fixing device being used to be correspondingly connected to the probe card and the carrier,” the fixing device can resist the stress caused by changes in air pressure to maintain a tightness of the test chamber. In the probe card apparatus with such structure, the stress generated caused by changes in air pressure can be avoided to be concentrated on at least one of the carrier and the probe card after the air pressure in the test chamber is adjusted by the air pressure adjusting device. In addition, partial stress can be resisted to avoid deformation of the carrier or the probe card, or even damage to the apparatus structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1A is a schematic structural view of a probe card apparatus according to one embodiment of the present disclosure;

FIG. 1B is a schematic structural view of the probe card apparatus according to one embodiment of the present disclosure;

FIG. 2 is a schematic structural view of the probe card apparatus according to one embodiment of the present disclosure;

FIG. 3 is a schematic structural view of the probe card apparatus according to one embodiment of the present disclosure;

FIG. 4 is a schematic perspective view of a storage container according to the present disclosure; and FIG. 5 is a schematic structural view of the probe card apparatus according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on. ” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

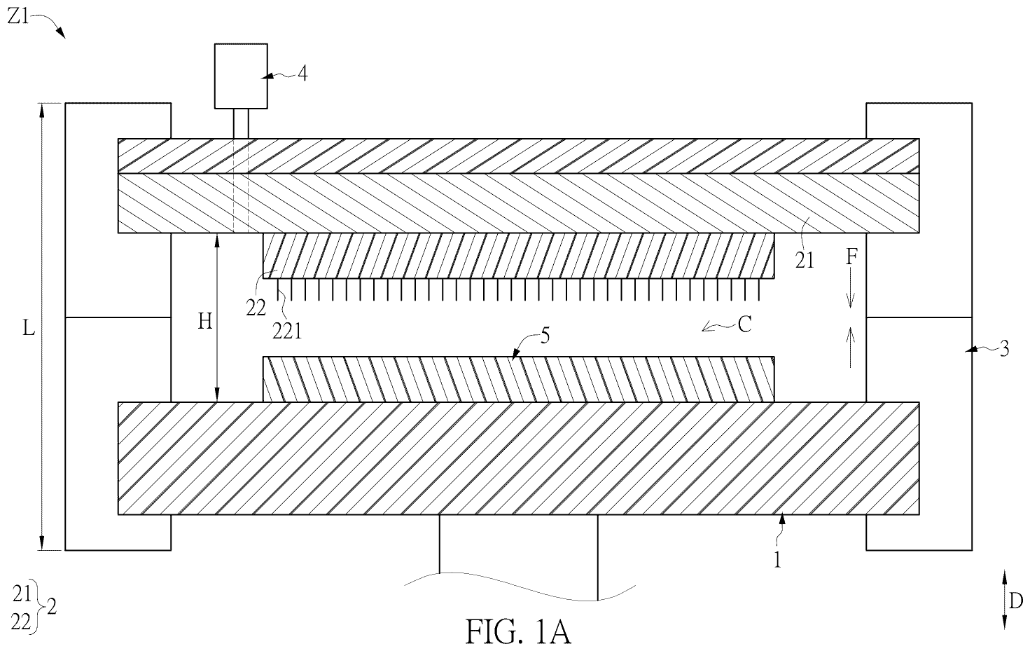

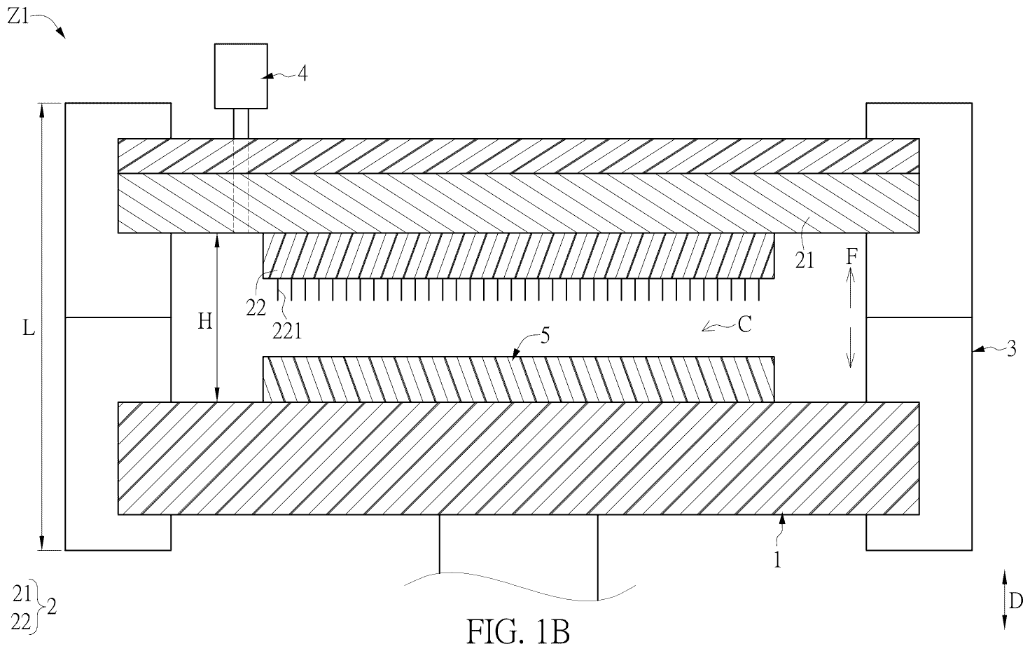

Reference is made to FIG. 1A and FIG. 1B that respectively show schematic structural views of a probe card apparatus Z1 according to one embodiment of the present disclosure. The probe card apparatus Z1 includes a carrier 1, a probe card 2, a fixing device 3, and an air pressure adjusting device 4. The carrier 1 is used to carry an object to be tested 5. The object to be tested 5 is for example a wafer or a chip. The probe card 2 includes a circuit board 21 and a probe head 22, and the probe head 22 includes a plurality of probes 221. The probe card 2 is disposed above the object to be tested 5, and the plurality of probes 221 are in contact with the object to be tested 5 for testing. The fixing device 3 is disposed between the probe card 2 and the carrier 1. The fixing device 3, the probe card 2, and the carrier 1 jointly define a test chamber C that is closed, and the object to be tested 5 is disposed in the test chamber C. The air pressure adjusting device 4 is spatially communicated with the test chamber C, and the air pressure adjusting device 4 is used to adjust an air pressure in the test chamber C to a predetermined air pressure. The initial air pressure in the test chamber C is, for example, one atm, and the predetermined air pressure can be less than one atm or greater than one atm. At least one of the carrier 1 and the probe card 2 is subject to a stress F at the predetermined air pressure. The fixing device 3 is used to resist the stress F to avoid deformation or damage to the carrier 1 or the probe card 2 as a result of the stress F. The stress F is generated in response to a change in air pressure in the test chamber C, and the stress F may cause the carrier 1 and the probe card 2 to separate from each other or to come close to each other (to squeeze each other), resulting in deformation or damage to the carrier 1 and the probe card 2. Therefore, the fixing device 3 is provided to disperse or bear the stress F on the carrier 1 and the probe card 2 to slow down the deformation and avoid damage to the carrier 1 and the probe card 2, which facilitates the testing of the object to be tested 5 by the probe card 2. At the predetermined air pressure, a length of the fixing device 3 can be determined based on a predetermined distance between the carrier 1 and the probe card 2, a predetermined over driving of the probe 221, and a predetermined needle pressure of the probe 221 on the object to be tested 5. In addition, the fixing device 3 is advantageous for maintaining integrity and tightness of the test chamber C.

As shown in FIG. 1A, taking a vacuum state of the test chamber C as an example, the air pressure adjusting device 4 draws gas from the test chamber C so that the predetermined air pressure is less than one atm. At this time, the test chamber C is in the vacuum state, in which the stress F drives the carrier 1 and the probe card 2 to squeeze each other. Through the fixing device 3, the carrier 1 and the probe card 2 can be fixed and supported to prevent the carrier 1 and the probe card 2 from moving or deforming.

As shown in FIG. 1B, in a case that the air pressure adjusting device 4 introduces gas into the test chamber C for pressurization, the stress F generated at this time drives the probe card 2 and the carrier 1 to separate from each other. In the embodiment shown in FIG. 1B, the fixing device 3 can also be a locker for connecting the probe card 2 to the carrier 1. Accordingly, the stress F on the probe card 2 and the carrier 1 can be dispersed to resist a force causing the separation of the probe card 2 from the carrier 1. In this manner, a distance H between the probe card 2 and the carrier 1 can be maintained, and the tightness of the test chamber C can also be maintained.

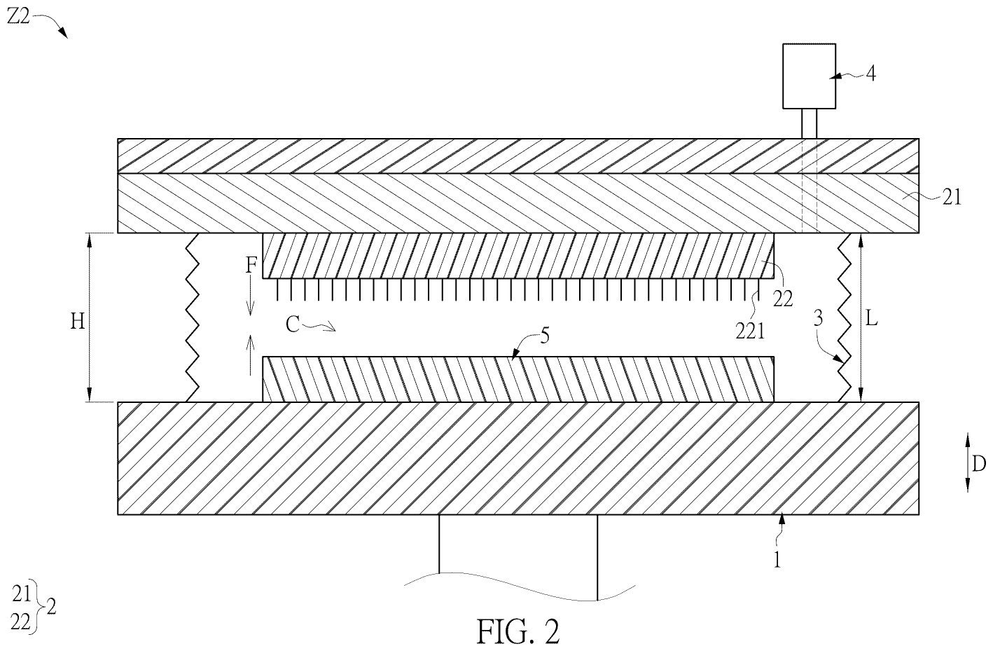

Reference is made to FIG. 2, in which a schematic structural view of a probe card apparatus Z2 according to one embodiment of the present disclosure is shown. In the present embodiment, the air pressure adjusting device 4 draws gas from the test chamber C so that the predetermined air pressure is less than one atm. At this time, the test chamber C is in the vacuum state, in which the stress F drives the carrier 1 and the probe card 2 to squeeze each other. Through the fixing device 3 with a screw structure, the carrier 1 and the probe card 2 can be fixed and supported to prevent the carrier 1 and the probe card 2 from moving, deforming, or squeezing each other.

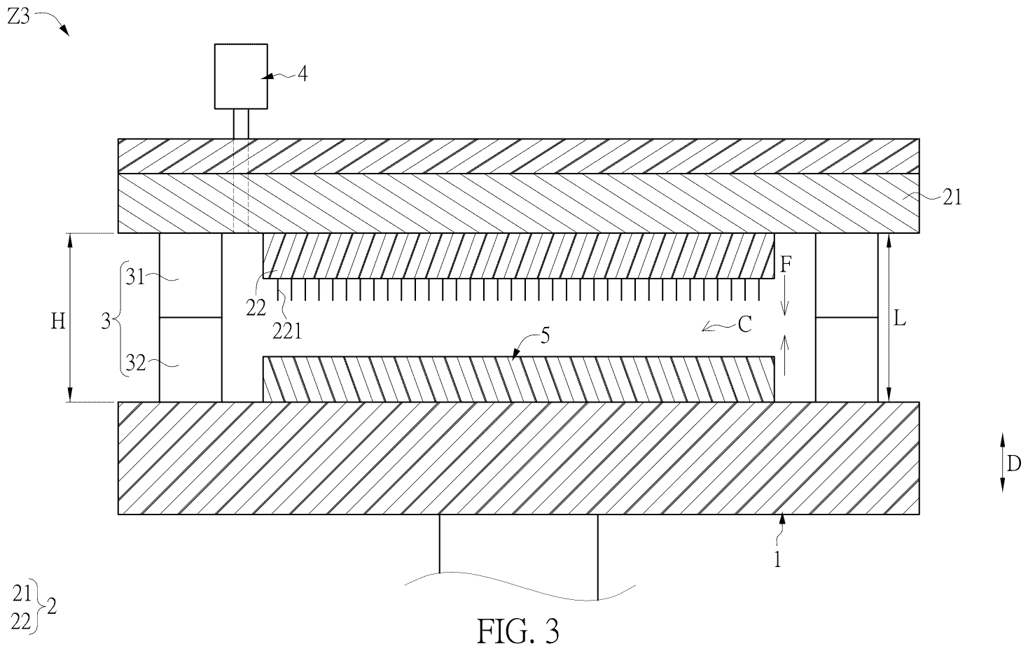

Reference is made to FIG. 3, in which a schematic structural view of a probe card apparatus Z3 according to one embodiment of the present disclosure is shown. In the present embodiment, the air pressure adjusting device 4 draws gas from the test chamber C so that the predetermined air pressure is less than one atm. At this time, the stress F in the test chamber C drives the carrier 1 and the probe card 2 to approach (squeeze) each other. The fixing device 3 includes a first engagement part 31 and a second engagement part 32, the first engagement part 31 is disposed on the probe card 2, and the second engagement part 32 is disposed on the carrier 1. The first engagement part 31 is correspondingly connected to the second engagement part 32, and a length L in a vertical direction D can be adjusted according to testing requirements by adjusting the first engagement part 31 and the second engagement part 32. In some embodiments, the first engagement part 31 and the second engagement part 32 are stoppers. The first engagement part 31 and the second engagement part 32 are tightly engaged to each other to resist the stress F, so that the distance H between the probe card 2 and the carrier 1 can be maintained, and the tightness of the test chamber C can be maintained.

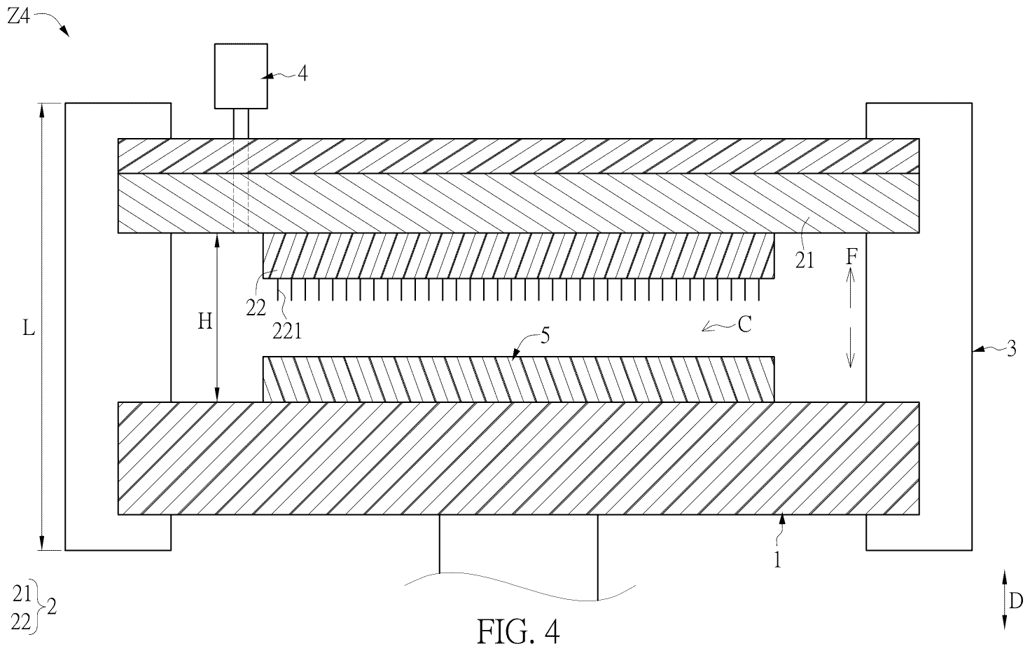

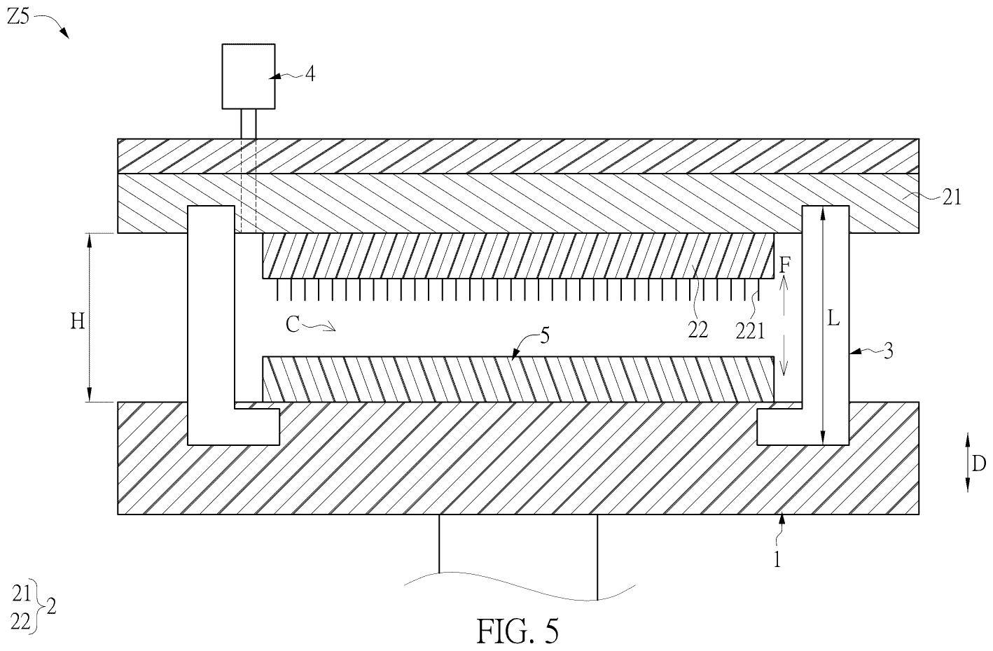

Reference is made to FIG. 4, in which a schematic structural view of a probe card apparatus Z4 according to one embodiment of the present disclosure is shown. In the present embodiment, the air pressure adjusting device 4 pressurizes the test chamber C by introducing gas into the test chamber C. At this time, the stress F generated drives the probe card 2 and the carrier 1 to separate from each other. In the present embodiment, the fixing device 3 is the locker for connecting the probe card 2 to the carrier 1. Accordingly, the stress F on the probe card 2 and the carrier 1 can be dispersed to resist the force causing the separation of the probe card 2 from the carrier 1. In this manner, the distance H between the probe card 2 and the carrier 1 can be maintained, and the tightness of the test chamber C can be maintained.

Reference is made to FIG. 5, in which a schematic structural view of a probe card apparatus Z5 according to one embodiment of the present disclosure is shown. The difference from the embodiment shown in FIG. 4 is the fixing device 3 configuration. In the present embodiment, the fixing device is also a retaining structure disposed between the carrier 1 and the probe card 2. The air pressure adjusting device 4 pressurizes the test chamber C by introducing gas into the test chamber C. At this time, the stress F generated drives the probe card 2 and the carrier 1 to separate from each other. The retaining structure is used to resist the stress F generated by pressurization, so that the distance H between the probe card 2 and the carrier 1 can be maintained, and the tightness of the test chamber C can be maintained.

In the embodiments shown in FIG. 1A and FIG. 1B, the fixing device 3 includes a clamping assembly. In the embodiment shown in FIG. 2, the fixing device 3 includes a screw fixing assembly. In addition, in some embodiments, the fixing device 3 includes an abutment assembly (as shown in FIG. 3). However, the present disclosure is not limited thereto. In some embodiments, the fixing device 3 includes a combination of the clamping assembly and the screw fixing assembly. Such fixing device 3 can be used in cases where the test chamber C is in the vacuum state or the gas-filled state. It should be noted that the fixing device 3 can be made of a metal structure or a plastic structure, but the present disclosure is not limited thereto.

In some embodiments, the length L of fixing device 3 in the vertical direction D can be adjusted. At the predetermined air pressure, the length L of fixing device 3 in the vertical direction D is determined corresponding to the distance H between the carrier 1 and the probe card 2. Depending on the distance H between the carrier 1 and the probe card 2 needed to be maintained at the predetermined air pressure (e.g., the vacuum state of less than one atm), the length L of fixing device 3 in the vertical direction D is adjusted. Accordingly, when the test chamber C is at the predetermined air pressure, the distance H between the carrier 1 and the probe card 2 can be maintained, which facilitates the probe card 2 to contact the object to be tested 5 for testing. In other words, the length L of the fixing device 3 is determined according to the distance H between the probe card 2 and the carrier 1 that is predetermined at the predetermined air pressure.

Further, in some embodiments, at one atm, the probes 221 of the probe card 2 apply an initial needle pressure (by measurement) on test points of the object to be tested 5 (e.g., the wafer) on the carrier 1. By adjusting the length L of the fixing device 3, a needle pressure of the probes 221 required to be applied to the object to be tested 5 when the test chamber C is in the vacuum state can be achieved for testing. In other words, the length L of the fixing device 3 is determined according to the needle pressure (by measurement) of the probes 221 that is predetermined to be applied to the object to be tested 5 at the predetermined air pressure.

In some embodiments, at one atm, the probe card 2 measures the object to be tested 5 on the carrier 1 with the over driving (the over driving is different corresponding to object to be tested 5 of different materials or distances), and a pressure for the over driving is slightly greater than the initial needle pressure described above. The length L of the fixing device 3 can be adjusted according to the required over driving, so that the probes 221 can test the object to be tested 5 with the required over driving when the test chamber C is in the vacuum state (i.e., less than one atm). In other words, the length L of the fixing device 3 is determined according to the over driving of the probes 221 that is predetermined to be applied to the object to be tested 5 at the predetermined air pressure.

In some embodiments, the gas supplied to the test chamber C by the air pressure adjusting device 4 is air, nitrogen, or an inert gas.

One of the beneficial effects of the present disclosure is that in the probe card apparatus provided by the present disclosure, by virtue of “the fixing device being used to be correspondingly connected to the probe card and the carrier,” the fixing device can resist the stress caused by changes in air pressure to maintain the tightness of the test chamber. In the probe card apparatus with such structure, the stress generated caused by changes in air pressure can be avoided to be concentrated on at least one of the carrier and the probe card after the air pressure in the test chamber is adjusted by the air pressure adjusting device. In addition, partial stress can be resisted to avoid deformation of the carrier or the probe card, or even damage to the apparatus structure.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A probe card apparatus comprising:
a carrier for carrying an object to be tested;
a probe card including a plurality of probes and disposed above the object to be tested, the plurality of probes being in contact with the object to be tested for testing the object to be tested;
a fixing device correspondingly connected to the probe card and the carrier, wherein the fixing device, the probe card, and the carrier jointly define a test chamber that is closed, and the object to be tested is disposed in the test chamber; and
an air pressure adjusting device spatially communicated with the test chamber and used to adjust an air pressure in the test chamber to a predetermined air pressure;
wherein at least one of the carrier and the probe card is subject to a stress at the predetermined air pressure;
wherein the fixing device is used to resist the stress.

2. The probe card apparatus according to claim 1, wherein the air pressure adjusting device draws gas from the test chamber, so that the predetermined air pressure is less than one atm.

3. The probe card apparatus according to claim 2, wherein, at the predetermined air pressure, a length of the fixing device in a vertical direction corresponds to a distance between the carrier and the probe card.

4. The probe card apparatus according to claim 2, wherein, at the predetermined air pressure, a length of the fixing device in a vertical direction corresponds to a needle pressure of the probe card applying to the object to be tested.

5. The probe card apparatus according to claim 2, wherein, at the predetermined air pressure, a length of the fixing device in a vertical direction corresponds to an over driving of the probe card applying to the object to be tested.

6. The probe card apparatus according to claim 1, wherein the air pressure adjusting device supplies gas into the test chamber, so that the predetermined air pressure is greater than one atm.

7. The probe card apparatus according to claim 6, wherein, at the predetermined air pressure, a length of the fixing device in a vertical direction corresponds to a distance between the carrier and the probe card.

8. The probe card apparatus according to claim 6, wherein, at the predetermined air pressure, a length of the fixing device in a vertical direction corresponds to a needle pressure of the probe card applying to the object to be tested.

9. The probe card apparatus according to claim 6, wherein, at the predetermined air pressure, a length of the fixing device in a vertical direction corresponds to an over driving of the probe card applying to the object to be tested.

10. The probe card apparatus according to claim 6, wherein the gas supplied to the test chamber by the air pressure adjusting device is air, nitrogen, or an inert gas.

11. The probe card apparatus according to claim 2, wherein the fixing device is made of at least one of a metal structure and a plastic structure.

12. The probe card apparatus according to claim 11, wherein the fixing device includes at least one of a clamping assembly and a screw fixing assembly.

13. The probe card apparatus according to claim 6, wherein the fixing device is made of at least one of a metal structure and a plastic structure.

14. The probe card apparatus according to claim 13, wherein the fixing device includes at least one of a clamping assembly and a screw fixing assembly.
